(19) United States
(12) Patent Application Publication
(10) Pub. No.: US 2014/0202387 A1
(43) Pub. Date: Jul. 24, 2014

(54) VERTICAL DIFFUSION FURNACE

(71) Applicant: KABUSHIKI KAISHA TOSHIBA, Tokyo (JP)

(72) Inventors: Yoshifumi NISHIO, Mie (JP); Takashi NAKAO, Mie (JP); Takaharu ITANI, Mie (JP); Akihiro TAKAMI, Tokyo (JP)

(73) Assignee: KABUSHIKI KAISHA TOSHIBA, Tokyo (JP)

(21) Appl. No.: 14/016,373

(22) Filed: Sep. 3, 2013

(30) Foreign Application Priority Data
Jan. 22, 2013 (JP) 2013-009444

(51) Int. Cl. H01L 21/67

(52) U.S. Cl. CPC H01L 21/67109
USPC 118/725

(57) ABSTRACT

A diffusion furnace includes a boat which supports a semiconductor wafer thereon and is rotatable together with the semiconductor wafer. A heater is arranged on the periphery of a core tube which houses the boat therein. The core tube includes a reaction gas supply pipe through which a reaction gas containing a dopant is supplied; and a cooling gas supply pipe through which a cooling gas is supplied toward an outer peripheral portion of the semiconductor wafer.

### CROSS-REFERENCE TO RELATED APPLICATION

This application is based upon and claims the benefit of priority from Japanese Patent Application No. 2013-009444, filed Jan. 22, 2013, the entire contents of which are incorporated herein by reference.

### FIELD

Embodiments described herein relate generally to a vertical diffusion furnace which is used in manufacturing a semiconductor device.

### BACKGROUND

Conventionally, a vertical diffusion furnace has been used where a heater is arranged on the periphery of a core tube which stores semiconductor wafers therein, and predetermined treatment is applied to the semiconductor wafers while rotating the semiconductor wafers. In such a vertical diffusion furnace, when the number of semiconductor wafers to be stored in the diffusion furnace is increased, the volume of the diffusion furnace is also increased, and it is necessary to increase an output of the heater. When a temperature of the vertical diffusion furnace is elevated, the semiconductor wafers are heated from an outer peripheral portion thereof in proximity to the heater. Accordingly, a temperature difference between a center portion and the outer peripheral portion of the semiconductor wafer is great and hence, there may be a case where the semiconductor wafer is deformed due to the difference in thermal stress between the center portion and the outer peripheral portion of the semiconductor wafer, thus generating a defect in crystal. The generation of a defect in crystal may be prevented by decreasing a temperature elevation rate, i.e., the temperature ramp rate. In this case, however, the temperature elevation step takes more time and thus lowers throughput of the manufacture of the semiconductor wafers.

Accordingly, a technique for uniformly heating the semiconductor wafers without lowering the temperature elevation rate becomes important, in addition to the uniform supplying of a dopant gas to the semiconductor wafers.

### DESCRIPTION OF THE DRAWINGS

FIG. 1 is a side cross-sectional view showing a vertical diffusion furnace according to a first embodiment;

FIG. 2 is a top cross-sectional view showing the positional relationship between a cooling gas supply pipe and a semiconductor wafer;

FIG. 3 is a graph showing a state of temperature of the semiconductor wafer;

FIG. 4 is a graph showing the relationship between a defect in crystal and a temperature of the semiconductor wafer;

FIG. 5 is a graph showing the relationship between a position where the semiconductor wafers are stored and a defect ratio; and

FIG. 6 is a partial cross-sectional view showing a vertical diffusion furnace according to a second embodiment.

### DETAILED DESCRIPTION

In general, according to one embodiment, provided is a vertical diffusion furnace which can suppress the generation of a defect in crystal by minimizing temperature distribution irregularity in a plane of a semiconductor wafer.

In general, according to one embodiment, provided is a vertical diffusion furnace having the following constitution. The diffusion furnace includes: a boat which is rotatable together with semiconductor wafers stored therein; and a core tube which houses the boat therein. A heater which heats the semiconductor wafers is arranged around the periphery of the core tube. The diffusion furnace also includes: a reaction gas supply pipe through which a reaction gas is supplied into the core tube; and a cooling gas supply pipe through which a cooling gas is supplied to the semiconductor wafers.

Hereinafter, a vertical diffusion furnace according to embodiments is explained in detail in conjunction with attached drawings. The present invention is not limited by the embodiments.

### First Embodiment

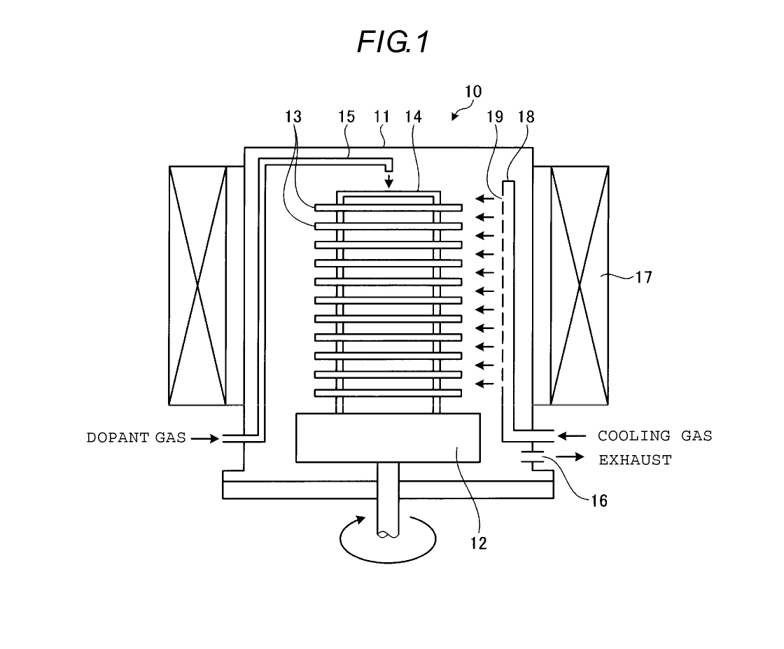

FIG. 1 is a view showing a vertical diffusion furnace according to the first embodiment. A vertical diffusion furnace 10 includes a boat 14 which stores a plurality of semiconductor wafers 13 therein in a core tube 11. To a boat receiver 12 which supports the boat 14 thereon, a predetermined rotational force is applied by a motor (not shown) so that the boat 14 is rotatable together with the semiconductor wafers 13 stored therein. A reaction gas supply pipe 15, through which a reaction gas containing a predetermined dopant which becomes a donor or an acceptor is supplied, is arranged in the inside of the core tube 11. For example, the reaction gas is supplied from above the boat 14.

A cooling gas supply pipe 18 is arranged in the inside of the core tube 11. The cooling gas supply pipe 18 has a plurality of gas supply ports 19. Each gas supply port 19 is preferably arranged at an intermediate position between positions of the respective semiconductor wafers 13 which are stored in the boat 14 and are arranged adjacent to each other. This provision is adopted for efficiently supplying a cooling gas to surfaces of the semiconductor wafers 13. As the cooling gas, an inert gas such as a helium (He) gas or an argon (Ar) gas at room temperature is used. When a temperature of the semiconductor wafers is elevated, the semiconductor wafers can also be sufficiently cooled by using the inert gas at room temperature. The temperature of the cooling gas isnot limited to room temperature, and it is sufficient that the temperature of the cooling gas is lower than the temperature of the semiconductor wafers to be cooled. The core tube 11 has an exhaust port 16. The reaction gas and the cooling gas which are supplied into the core tube 11 are exhausted through the exhaust port 16. A heater 17 is arranged on the periphery of the core tube 11.

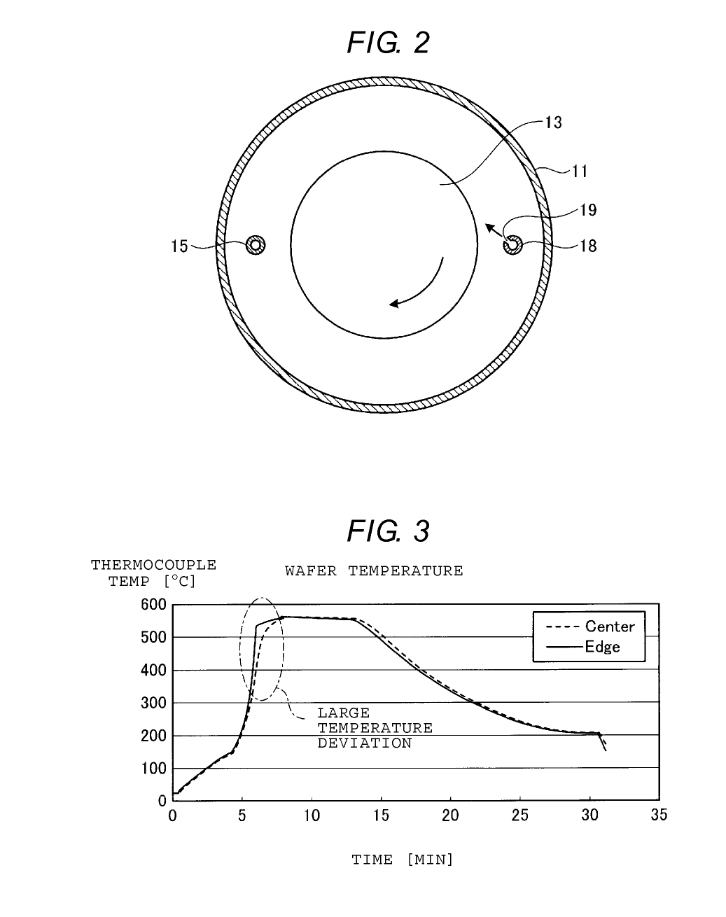

FIG. 2 is a view showing the positional relationship between the cooling gas supply pipe 18 and the semiconductor wafers 13. The cooling gas supply pipe 18 is arranged in the inside of the core tube 11. The cooling gas supply pipe 18 is provided such that the gas supply ports 19 formed in the cooling gas supply pipe 18 are directed in an inclined direction toward the outer periphery of the semiconductor wafers 13. The inclination may be a predetermined angle from a line which connects the center of the core tube 11 (longitudinal axis of the core tube 11) and the center of the cooling gas supply pipe (longitudinal axis of the cooling gas supply pipe 18). Alternatively, the cooling gas supply pipe may be formed of a tube which is rotatable in the horizontal direction (along the longitudinal axis thereof) so as to allow the gas supply ports to be inclined toward the outer periphery of the semiconductor wafers. By arranging the gas supply ports in such a manner, the outer peripheral portions of the semiconductor wafers 13 can be effectively cooled by the cooling gas discharged through the gas supply ports 19 and thereby a temperature deviation generated between the center portions and the outer peripheral portions of the semiconductor wafers 13 is suppressed during a temperature ramp-up (i.e., when the temperature of the semiconductor wafers 13 is elevated).

FIG. 3 is a graph showing a state of temperature of the semiconductor wafers 13. A time elapsed from the start of temperature ramp-up of the vertical diffusion furnace is shown on the abscissa, and a temperature of thermocouples (not shown) mounted on the semiconductor wafers 13 is shown on the ordinate. A broken line indicates a temperature of the thermocouple mounted on the center portions of the semiconductor wafers 13, and a solid line indicates a temperature of the thermocouples mounted on the outer peripheral portions of the semiconductor wafers 13. From the result shown in FIG. 3, it is understood that a temperature difference (temperature deviation) between the center portions and the outer peripheral portions of the semiconductor wafers 13 becomes great after a lapse of approximately 7 minutes from the start of temperature elevation of the vertical diffusion furnace. By cooling the outer peripheral portions of the semiconductor wafers 13 by supplying the cooling gas when the temperature deviation becomes large, the temperature difference (temperature deviation) between the outer peripheral portion and the center portion can be efficiently decreased.

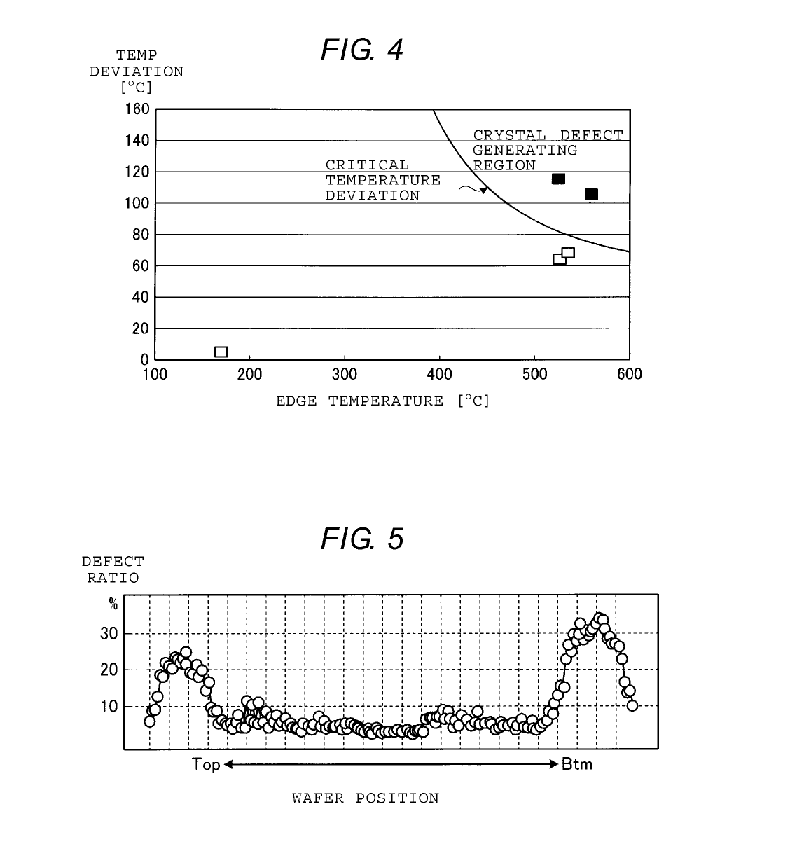

FIG. 4 is a graph showing the relationship between a crystal defect generated in the semiconductor wafers 13 corresponding to a temperature of the semiconductor wafers 13. A temperature of the outer peripheral portions (Edge) of the semiconductor wafers 13 is taken on the abscissa, and the temperature difference (temperature deviation) between the outer peripheral portions and the center portions of the semiconductor wafers 13 is taken on the ordinate. In the graph, a solid line which indicates a critical temperature deviation indicates a critical temperature deviation at which a defect in crystal is generated in the semiconductor wafers 13. When the temperature deviation exceeds the critical temperature deviation, defects in crystal are generated in the semiconductor wafers 13. However, by performing a control where the outer peripheral portions of the semiconductor wafers 13 are cooled with the cooling gas so that the temperature deviation between the center portions and the outer peripheral portions of the semiconductor wafers 13 is suppressed within the critical temperature deviation, the generation of defects in crystal in the semiconductor wafers 13 can be suppressed. For example, a control is performed such that the temperature deviation between the center portions and the outer peripheral portions of the semiconductor wafers 13 is 40° C. or below.

FIG. 5 is a graph showing the relationship between the position where the semiconductor wafers 13 on the boat are stored and a defect ratio. A height of the storing positions of the semiconductor wafers 13 is taken on the abscissa, and the defect ratio is taken on the ordinate. The defect ratio is set such that a defect is generated when a leak current is generated in elements (not shown) built in the semiconductor wafers 13. As shown in FIG. 5, the semiconductor wafers 13 stored in a top portion (Top) of the boat 14 and the semiconductor wafers 13 stored in a bottom portion (Btm) of the boat 14 exhibit a high defect ratio. The reason is as follows. In the case of a vertical diffusion furnace where a large number of semiconductor wafers 13 are stored, in order to make the temperature in the core tube uniform, a temperature control is performed so as to set temperatures of the heaters mounted on an upper portion and a lower portion of the core tube higher than temperatures of the heaters mounted on other portions of the core tube. Due to such a temperature control, however, the temperature difference (temperature deviation) between the center portion and the outer peripheral portion becomes greater in the semiconductor wafers 13 stored in the top portion and the bottom portion of the boat 14, respectively. By increasing a supply amount of the cooling gas at the top portion and the bottom portion of the boat 14, a temperature control based on magnitude of the temperature deviation can be realized. For example, by setting a size of the gas supply ports 19 (shown in FIGS. 1 and 2) of the cooling gas supply pipe 18 corresponding to the top portion and the bottom portion of the boat 14 to be greater than a size of the gas supply ports 19 of a middle portion of the cooling gas supply pipe 18, the supply amount of the cooling gas can be increased and thereby a cooling effect can be enhanced.

### Second Embodiment

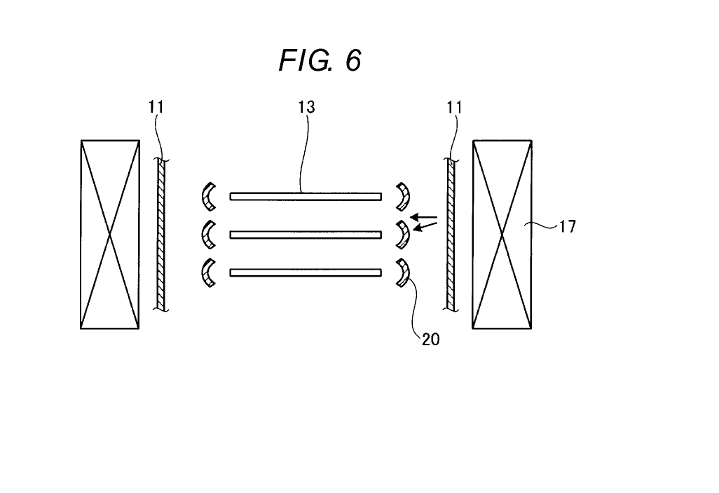

FIG. 6 is a partial view showing a cross-section of a vertical diffusion furnace according to the second embodiment. Constitutional elements of the second embodiment corresponding to the constitutional elements of the first embodiment are given the same symbols, and the explanation of such constitutional elements is omitted for brevity. In this embodiment, corresponding to storing positions of semiconductor wafers 13 are stored in a boat (not shown), a heat insulating plate 20 is arranged between a heater 17 and the semiconductor wafers 13. The heat insulating plate 20 is made of quartz, for example. Each heat insulating plate 20 is held by a predetermined holding jig (not shown).

According to this embodiment, direct radiant heat irradiated from the heater 17 toward outer peripheral portions of the semiconductor wafers 13 is blocked by the heat insulating plates 20. Due to such a constitution, temperature elevation of the outer peripheral portions of the semiconductor wafers 13 is suppressed and hence, a temperature deviation between the center portions and the outer peripheral portions of the semiconductor wafers 13 can be suppressed. Accordingly, the generation of defects in crystal in the semiconductor wafers 13 can be suppressed. To prevent direct radiant heat from being irradiated toward outer peripheries of the semiconductor wafers 13, the vertical diffusion furnace may be configured such that the whole boat 14 is surrounded by a heat insulating plate (not shown) having the constitution where light transmittance values of portions of the heat insulating plate corresponding to storing positions of the semiconductor wafers 13 comprise low values.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A diffusion furnace, comprising:
a rotatable boat which supports a semiconductor wafer thereon;
a core tube which houses the rotatable boat therein;
a heater which heats the semiconductor wafer in the core tube;
a reaction gas supply pipe through which a reaction gas is supplied into the core tube; and
a cooling gas supply pipe through which a cooling gas is supplied to the semiconductor wafer.

2. The diffusion furnace according to claim 1, wherein the cooling gas is an inert gas.

3. The diffusion furnace according to claim 2, wherein the cooling gas supply pipe is provided between the boat and the heater.

4. The diffusion furnace according to claim 3, wherein the cooling gas supply pipe includes a plurality of gas supply ports formed along a longitudinal axis thereof to direct the cooling gas radially therefrom.

5. The diffusion furnace according to claim 4, wherein the gas supply ports formed in an upper portion and a lower portion of the gas supply pipe have a size greater than a size of the gas supply ports formed in a middle portion of the gas supply pipe.

6. The diffusion furnace according to claim 4, wherein the plurality of gas supply ports are positioned to direct the cooling gas at an angle determined from a line which connects the center of the core tube and the center of the cooling gas supply pipe.

7. The diffusion furnace according to claim 1, wherein the cooling gas supply pipe is provided between the boat and the heater.

8. The diffusion furnace according to claim 7, wherein the cooling gas supply pipe includes a plurality of gas supply ports formed along a longitudinal axis thereof to direct the cooling gas radially therefrom.

9. The diffusion furnace according to claim 8, wherein the gas supply ports formed in an upper portion and a lower portion of the gas supply pipe have a size greater than a size of the gas supply ports formed in a middle portion of the gas supply pipe.

10. The diffusion furnace according to claim 8, wherein the plurality of gas supply ports are positioned to direct the cooling gas at an angle determined from a line which connects the center of the core tube and the center of the cooling gas supply pipe.

11. The diffusion furnace according to claim 8, wherein the cooling gas is provided after a predetermined lapse of time from the start of the temperature ramp-up by the heater.

12. The diffusion furnace according to claim 1, wherein the cooling gas supply pipe includes a plurality of gas supply ports formed along a longitudinal axis thereof to direct the cooling gas radially therefrom.

13. The diffusion furnace according to claim 12, wherein the gas supply ports formed in an upper portion and a lower portion of the gas supply pipe have a size greater than a size of the gas supply ports formed in a middle portion of the gas supply pipe.

14. The diffusion furnace according to claim 12, wherein the plurality of gas supply ports are positioned to direct the cooling gas at an angle determined from a line which connects the center of the core tube and the center of the cooling gas supply pipe.

15. The diffusion furnace according to claim 1, wherein the cooling gas supply pipe includes a plurality of gas supply ports formed along a longitudinal axis thereof to direct the cooling gas radially therefrom.

16. The diffusion furnace according to claim 15, wherein the gas supply ports formed in an upper portion and a lower portion of the gas supply pipe have a size greater than a size of the gas supply ports formed in a middle portion of the gas supply pipe.

17. The diffusion furnace according to claim 15, wherein the plurality of gas supply ports are positioned to direct the cooling gas at an angle determined from a line which connects the center of the core tube and the center of the cooling gas supply pipe.

18. A diffusion furnace, comprising:
a rotatable boat which supports a semiconductor wafer thereon;
a core tube which houses the rotatable boat therein;
a heater which heats the semiconductor wafer in the core tube;
a reaction gas supply pipe through which a reaction gas is supplied into the core tube; and
a cooling gas supply pipe positioned between the heater and the boat, the cooling gas supply pipe having a plurality of gas supply ports through which an inert cooling gas is directed toward a periphery of the semiconductor wafer.

19. The diffusion furnace according to claim 18, wherein the gas supply ports formed in an upper portion and a lower portion of the gas supply pipe have a size greater than a size of the gas supply ports formed in a middle portion of the gas supply pipe.

20. A diffusion furnace, comprising:
a rotatable boat which supports a semiconductor wafer thereon;
a core tube which houses the rotatable boat therein;
a heater which heats the semiconductor wafer in the core tube;
a reaction gas supply pipe through which a reaction gas is supplied into the core tube; and
a cooling gas supply pipe positioned between the heater and the boat, the cooling gas supply pipe having a plurality of gas supply ports through which an inert cooling gas is directed toward a periphery of the semiconductor wafer, wherein the gas supply ports formed in an upper portion and a lower portion of the gas supply pipe have a size greater than a size of the gas supply ports formed in a middle portion of the gas supply pipe.
